(19) United States
(12) Patent Application Publication
(10) Pub. No.: US 2025/0221094 A1
(43) Pub. Date: Jul. 3, 2025

(54) METHOD FOR PRODUCING A GROWTH SUBSTRATE, GROWTH SUBSTRATE AND RADIATION-EMITTING SEMICONDUCTOR CHIP

(71) Applicant: ams-OSRAM International GmbH, Regensburg (DE)

(72) Inventors: Hans-Jürgen LUGAUER, Sinzing (DE); Adrian Stefan AVRAMESCU, Regensburg (DE); Marc HOFFMANN, Regensburg (DE); Viola Miran KUELLER, Barbing (DE); Christoph MARGENFELD, Braunschweig (DE); Lukas PETERS, Braunschweig (DE); Andreas WAAG, Wuerzburg (DE)

(21) Appl. No.: 18/850,572

(22) PCT Filed: Mar. 21, 2023
(86) PCT No.: PCT/EP2023/057174

§ 371 Date: Sep. 25, 2024

(30) Foreign Application Priority Data
Apr. 6, 2022 (DE) 102022108234.2

(51) Int. Cl. H10H 20/01; H10H 20/825

(52) U.S. Cl. CPC H10H 20/01335; H10H 20/8252

(57) ABSTRACT

A method for producing a growth substrate (1) is specified, the method comprising the following steps:
providing a substrate (2) with a main surface (3),
applying a semiconductor layer (4) comprising a nitride compound semiconductor material to the main surface (3) of the substrate (2),
inserting of impurity atoms of a first type into the semiconductor layer (4) by ion implantation,
tempering of the semiconductor layer (4) after inserting the impurity atoms of the first type.

A growth substrate and a radiation-emitting semiconductor chip are also specified.

### CROSS-REFERENCE TO RELATED APPLICATIONS

This is a national phase of International Application PCT/EP2023/057174, which was filed on Mar. 21, 2023, and which claims priority to German Application DE 10 2022 108 234.2, which was filed on Apr. 6, 2022, the entire contents of each of which are incorporated herein by reference.

### Technical-Field

A method for producing a growth substrate, a growth substrate and a radiation-emitting semiconductor chip are specified.

### BACKGROUND

An object to be solved is to specify a method for producing a growth substrate with improved material properties, in particular with a low defect density. A further object to be solved is to provide a growth substrate which exhibits improved material properties. Furthermore, a radiation-emitting semiconductor chip comprising an increased efficiency is to be specified.

### SUMMARY

These objects are solved by the method according to claim 1, the growth substrate according to claim 12 and the radiation-emitting device according to claim 17.

Advantageous embodiments and developments of the method, the growth substrate and the radiation-emitting device are described with reference to the dependent claims.

A method for producing a growth substrate is specified. For example, the growth substrate is a growth substrate for an epitaxial semiconductor layer sequence configured to generate or detect electromagnetic radiation.

According to an embodiment of the method for producing a growth substrate, a substrate is provided. The substrate comprises a main surface. In particular, the substrate comprises high temperature stable materials. “High temperature stable material” means here and in the following, for example, that the material shows no decomposition or no change in aggregate state at temperatures above 1400° C. In other words, high temperature stable materials are chemically and mechanically stable at temperatures above 1400° C. The substrate preferably comprises or consists of one of the following materials: high-temperature stable metals, for example tungsten, sapphire, silicon carbide.

According to an embodiment of the method, a semiconductor layer is applied to the main surface of the substrate. The semiconductor layer is preferably applied directly to the substrate. The semiconductor layer comprises a nitride compound semiconductor material, for example aluminum nitride. A nitride compound semiconductor material is in particular a binary, ternary or quaternary compound which contains at least one element from the third main group, such as B, Al, Ga, and In, and nitrogen. Nitride compound semiconductor materials contain in particular nitrogen, such as the materials from the system InₓAl_{y}Ga_{1-x-y}N with 0≤x≤1, 0≤y≤1 and x+y≤1.

According to an embodiment, the semiconductor layer is applied to the main surface of the substrate by physical vapor deposition (PVD), in particular sputtering, or by epitaxy, in particular metal organic chemical vapor phase epitaxy (MOVPE) or hydride vapor phase epitaxy (HVPE).

In particular, it is difficult to apply a semiconductor layer of high quality with these methods. For example, the semiconductor layers deposited by the above-described methods comprise a high defect density. A defect can be a point defect, such as an impurity, a void or an interstitial atom, or a dislocation, such as a step dislocation or a screw dislocation. The defects can reduce the quality, in particular a crystal quality, of the semiconductor layer and lead to absorption, reduced quantum efficiency, leakage currents, internal stress, undesired doping, reduced lifetime and/or reduced reliability.

The internal stress can be caused by lattice mismatch of the semiconductor layer to the substrate or by a difference between a thermal expansion coefficient of the semiconductor layer and the substrate, for example during cooling. The internal stress in the semiconductor layer causes, for example, the growth substrate to bend, cracks to form in the semiconductor layer or in the substrate, or dislocations to form due to lattice relaxation.

According to an embodiment of the method, impurity atoms of a first type are inserted into the semiconductor layer by ion implantation. In particular, the impurity atoms of the first type are inserted into the semiconductor layer in such a way that they are homogeneously distributed in the semiconductor layer. Alternatively, it is possible that the impurity atoms of the first type are introduced in such a way that a gradient of the impurity atoms of the first type is formed in the semiconductor layer. Here and in the following, the term impurity atoms refers to all those atoms that were not already present in the semiconductor layer after the semiconductor layer was applied. For example, if the semiconductor layer comprises aluminum nitride, aluminum atoms and nitrogen atoms that are inserted into the semiconductor layer by ion implantation are also impurity atoms. Ion implantation preferably occurs via a surface of the semiconductor layer that is opposite the main surface of the substrate.

During ion implantation, ions of the impurity atoms are generated in an ion source. The ions are then extracted from the ion source with the help of a pre-accelerator and selected in a mass separator. The selected ions are then accelerated with an acceleration energy. In this way, an ion beam is obtained which is deflected onto a surface of a material, here in particular onto a surface of the semiconductor layer. After the ions hit the surface, the ions penetrate the material, wherein the charge of the ions is neutralized and thus the impurity atoms are inserted into the material. A penetration depth of the impurity atoms into the material, in particular into the semiconductor layer, depends, for example, on the material, the type of impurity atoms and the acceleration energy of the corresponding ions.

By inserting impurity atoms, point defects, such as interstitial atoms and defects, are in particular introduced into the semiconductor layer. The defect density in the semiconductor layer is therefore in particular increased by the insertion of impurity atoms.

According to an embodiment of the method, the semiconductor layer is tempered after inserting the impurity atoms of the first type. Tempering means here and in the following in particular that the semiconductor layer is heated for a certain time to a temperature which is above room temperature. Tempering preferably results in recrystallization of the nitride compound semiconductor material in the semiconductor layer. This results in defect annihilation, dislocation bending and/or dislocation reduction. In other words, tempering preferably reduces the defect density in the semiconductor layer.

During tempering, it is possible for the impurity atoms of the first type to be incorporated into the semiconductor layer.

Alternatively, the impurity atoms of the first type can be removed from the semiconductor layer by the tempering. By incorporating the impurity atoms of the first type, it is possible, for example, to modify material properties such as thermal and/or electrical conductivity of the semiconductor layer.

Furthermore, a material with a different lattice constant to the original material of the semiconductor layer can be produced by incorporating the impurity atoms of the first type. This results in particular in a reduction or at least mitigation of undesirable stress effects. This enables improved growth of subsequent layers.

According to an embodiment of the method for producing a growth substrate, the method comprises the following steps:
providing a substrate with a main surface,
applying a semiconductor layer comprising a nitride compound semiconductor material on the main surface of the substrate,
inserting of impurity atoms of a first type into the semiconductor layer by ion implantation,
tempering of the semiconductor layer after inserting the impurity atoms of the first type.

For example, the method steps are performed in the specified order.

With the method described herein, it is advantageously possible to produce a growth substrate with a semiconductor layer comprising a low defect density.

Compared to growth substrates with a semiconductor layer comprising a nitride compound semiconductor material, which are produced without the insertion of impurity atoms into the semiconductor layer and, for example, the material properties are only improved by tempering, the growth substrate produced with the method described herein has a lower defect density in the semiconductor layer and thus improved material properties. In particular, the growth substrate comprises a lower absorption and/or a lower internal stress compared to conventional growth substrates.

According to an embodiment of the method, impurity atoms of a second type are inserted into the semiconductor layer by ion implantation. The impurity atoms of the second type are different from the impurity atoms of the first type. In other words, the impurity atoms of the first type are a different chemical element than the impurity atoms of the second type. The impurity atoms of the second type can either be incorporated into the semiconductor layer or removed from the semiconductor layer by tempering. For example, the impurity atoms of the first type are incorporated into the semiconductor layer by tempering, whereas the impurity atoms of the second type are removed from the semiconductor layer by tempering or vice versa. However, it is also possible that both the impurity atoms of the first type and the impurity atoms of the second type are incorporated into the semiconductor layer or removed from the semiconductor layer. The impurity atoms of the second type can be inserted into the semiconductor layer in a homogeneously distributed manner or with a gradient.

According to an embodiment of the method, the impurity atoms of the first type and/or the impurity atoms of the second type are selected from the group formed by the elements Be, Mg, B, Al, Ga, In, C, Si, Ge, N, P, As, O, He, Ne, and Ar. In particular, the elements Ga, In, He, Ne, and Ar are at least partially removed from the semiconductor layer by tempering. In the case of the other elements, it is possible that they are incorporated into the semiconductor layer by tempering.

Advantageously, the impurity atoms of the first type and/or the impurity atoms of the second type incorporated into the semiconductor layer adjust the thermal and/or electrical conductivity of the semiconductor layer. In this way, semiconductor layers can be provided which comprise an increased or decreased thermal and/or electrical conductivity compared to the semiconductor layer without impurity atoms of the first type and/or without impurity atoms of the second type.

In particular, impurities, which have, for example, diffused from the substrate into the semiconductor layer, collect in the immediate vicinity of Be and/or Mg during tempering. This allows the impurities to be removed from a surface of the semiconductor layer, for example.

According to an embodiment of the method, the semiconductor layer comprises a nitride compound semiconductor material with a large band gap. In particular, the nitride compound semiconductor material is aluminum nitride or aluminum gallium nitride. For example, the nitride compound semiconductor material comprises an aluminum content of at least 50%. With the method described herein, it is in particular possible to insert impurity atoms into such nitride compound semiconductor materials, which is only possible at great expense with other methods.

According to an embodiment of the method, the semiconductor layer comprises aluminum nitride. Due to different lattice constants, the aluminum gallium nitride layer cannot be grown directly on a substrate, such as sapphire, by epitaxy methods, in particular MOVPE, without a high defect density occurring. Therefore, aluminum gallium nitride is grown in particular on a semiconductor layer with aluminum nitride. In order to obtain an aluminum gallium nitride layer that is as defect-free as possible, a semiconductor layer with aluminum nitride with a low defect density, such as can be obtained by the method described herein, is required.

According to an embodiment of the method, the impurity atoms of the first type are boron. In particular, Si, Mg or O are inserted as impurity atoms of the second type. If the semiconductor layer comprises aluminum nitride, aluminum boron nitride can be produced by introducing boron.

Aluminum boron nitride produced by MOVPE comprises a maximum boron content of 3%. In contrast, the method described herein can be used to produce a semiconductor layer with aluminum boron nitride with a boron content of more than 3% starting from a semiconductor layer with aluminum nitride.

In particular, boron nitride comprises a higher thermal conductivity than aluminum nitride. Therefore, the thermal conductivity of the semiconductor layer can be increased by inserting boron.

According to an embodiment of the method, the tempering is carried out at a temperature of 1400° C. to 1800° C., both inclusive. For example, tempering is carried out at a temperature of approximately 1700° C.

According to an embodiment of the method, the tempering is carried out for a duration of at most 10 hours, in particular at most 7 hours. Preferably, the tempering is carried out for a duration of one hour up to and including 5 hours.

According to an embodiment of the method, ions of the impurity atoms of the first type and/or ions of the impurity atoms of the second type impinge with a fluence between 5·10¹⁴ cm⁻² and 5·10¹⁶ cm⁻², both inclusive, on the semiconductor layer during ion implantation. The fluence can also be referred to as the implantation dose. In particular, with a higher fluence, a higher defect density and/or a higher concentration of impurity atoms can be generated in the semiconductor layer.

According to an embodiment of the method, during the ion implantation, the ions of the impurity atoms of the first type and/or the ions of the impurity atoms of the second type are accelerated with an acceleration energy between 10 keV and 1000 keV, both inclusive. For example, particularly in the case of boron as impurity atoms of the first type and/or the second type, the ions are accelerated with an acceleration energy between 10 keV and 40 keV, both inclusive. The higher the acceleration energy during ion implantation, the deeper the impurity atoms of the first type and/or the impurity atoms of the second type can penetrate into the semiconductor layer.

According to an embodiment of the method, so many impurity atoms of the first type and/or impurity atoms of the second type are inserted into the semiconductor layer during the ion implantation that the theoretical amorphization threshold of the semiconductor layer is at least reached, in particular exceeded. The theoretical amorphization threshold of the semiconductor layer is characterized in particular by the fact that the semiconductor layer comprises such a large number of point defects at this threshold that the semiconductor layer is amorphous. This means that from the theoretical amorphization threshold, the semiconductor layer is no longer present in crystalline form, for example, and atoms in the semiconductor layer comprise no short-range order and/or no long-range order.

According to an embodiment of the method, after tempering, the semiconductor layer comprises a dislocation density of at most 1·10⁹ cm⁻², in particular of at most 5·10⁸ cm⁻². Before inserting of the impurity atoms of the first type and/or the impurity atoms of the second type, the semiconductor layer comprises, for example, a dislocation density of at least 1·10¹⁰ cm⁻². By the method for producing a growth substrate described herein, it is therefore preferably possible to produce a growth substrate with a semiconductor layer comprising a high quality due to the low dislocation density.

According to an embodiment of the method, the semiconductor layer comprises a thickness of at most 1000 nanometers, in particular of at most 500 nanometers. Advantageously, the method described herein can therefore be used to produce growth substrates with a semiconductor layer comprising a low thickness. In particular, the low thickness of the semiconductor layer makes it possible to provide a growth substrate comprising a reduced curvature.

According to an embodiment of the method, a plurality of ion implantation steps are performed during inserting the impurity atoms of the first type and/or the impurity atoms of the second type. In particular, the impurity atoms and/or the acceleration energies of the ions differ between different ion implantation steps. For example, this results in a gradient of the impurity atoms of the first type and/or the second type and/or a gradient of the defect density in the semiconductor layer. In particular, the gradient starts from the main surface of the substrate. The gradient of the defect density generates, for example, a gradient of the internal stress in the semiconductor layer, which counteracts the internal stress already present in the semiconductor layer.

A plurality of ion implantation steps is understood here and in the following to mean in particular more than two ion implantation steps, for example more than five ion implantation steps.

According to an embodiment of the method, a mask is applied in places to the semiconductor layer before inserting the impurity atoms of the first type and/or the impurity atoms of the second type. In particular, the mask is applied to the surface of the semiconductor layer opposite the main surface of the substrate. Due to the mask it possible to prevent impurity atoms of the first type and/or the second type from being inserted into regions of the semiconductor layer. In other words, in the regions of the semiconductor layer covered by the mask, the defect density is not increased by the ion implantation.

In this way, for example, it is possible for lateral stress patterns to be generated in the semiconductor layer. The lateral stress patterns can advantageously lead to a curvature or annihilation of dislocations.

According to an embodiment of the method, the mask comprises the shape of a regular grid. In particular, grid lines or intersections of the grid lines of the regular grid are covered by the mask. For example, the regular grid is a hexagonal grid or a uniform rectangular grid.

According to an embodiment of the method, a material of the mask is selected from a group formed by a photoresist, a metal such as Cr or Ti, silicon dioxide and silicon nitride. In the case of a mask of the photoresist, the mask is preferably removed prior to tempering.

According to an embodiment of the method, the mask comprises a thickness in the region of 300 nanometers to 5 micrometers, both inclusive. In particular, the thickness of the mask is selected such that during the inserting of the impurity atoms of the first type and/or the impurity atoms of the second type, the impurity atoms cannot penetrate the mask.

According to an embodiment of the method, a plurality of ion implantation steps is performed and at least part of the mask is removed between two ion implantation steps. In particular, the impurity atoms of the first type and/or the impurity atoms of the second type and/or the acceleration energies of the ions differ between different ion implantation steps. For example, the acceleration energy is reduced after at least partial removal of the mask.

By at least partially removing the mask, it is possible to create first regions in the semiconductor layer whose cross-section area decreases starting from the main surface of the substrate. In particular, the cross-section area extends parallel to the main surface of the substrate. In the first regions, the defect density is in particular not increased by the ion implantation. Furthermore, the first regions preferably comprise no impurity atoms of the first type and/or impurity atoms of the second type. The first regions can attract curved dislocations in the semiconductor layer due to lateral stress fields. In this way, a continuation of the dislocations up to the surface of the semiconductor layer opposite the main surface of the substrate can be prevented.

A growth substrate is further specified. Preferably, the growth substrate is produced with the method described herein. Features and embodiments described in connection with the method for producing a growth substrate also apply to the growth substrate and vice versa.

According to an embodiment of the growth substrate, the growth substrate comprises a substrate with a main surface. In particular, the substrate is transparent to electromagnetic radiation in the ultraviolet to visible region of the electromagnetic spectrum. For example, the substrate comprises or consists of sapphire.

According to an embodiment, the growth substrate comprises a semiconductor layer on the main surface of the substrate. The semiconductor layer comprises a nitride compound semiconductor material, for example aluminum nitride. In particular, the semiconductor layer comprises a low dislocation density of, for example, at most 1·10⁹ cm⁻². The growth substrate is therefore advantageously suitable as a growth substrate for epitaxial semiconductor layer sequences that are configured to generate or detect electromagnetic radiation.

According to an embodiment of the growth substrate, the semiconductor layer comprises impurity atoms of the first type. In particular, the impurity atoms of the first type improve the material properties of the semiconductor layer. For example, the impurity atoms of the first type increase the thermal conductivity of the semiconductor layer.

According to an embodiment of the growth substrate, the semiconductor layer comprises impurity atoms of a second type which is different from the first type.

Due to the impurity atoms of the first type and/or the impurity atoms of the second type it possible to provide a semiconductor layer with a ternary nitride compound semiconductor material, i.e. a nitride compound semiconductor material consisting of three elements. Such a semiconductor layer is particularly suitable as a buffer layer. The growth substrate with such a semiconductor layer is advantageously suitable for growing epitaxial semiconductor layer sequences in a lattice-matched or at least only slightly lattice-mismatched manner. As a result, an epitaxial semiconductor layer sequence can be grown on the growth substrate with a low dislocation density. This leads in particular to higher efficiency and higher reliability of a later device.

According to an embodiment of the growth substrate, the semiconductor layer comprises a gradient of the impurity atoms of the first type and/or a gradient of the impurity atoms of the second type starting from the main surface of the substrate. For example, a concentration of the impurity atoms of the first type and/or a concentration of the impurity atoms of the second type increases or decreases from the main surface of the substrate into the semiconductor layer. In particular, the gradient of the impurity atoms of the first type and the gradient of the impurity atoms of the second type may be opposite or equal.

According to an embodiment of the growth substrate, the semiconductor layer comprises first regions and second regions. In particular, the regions are arranged directly adjacent to each other. Preferably, the first regions and the second regions are arranged adjacent to each other in a lateral direction. In particular, the lateral direction is arranged parallel to the main surface of the substrate. The first regions are in particular those regions which are covered by the mask during the method of producing the growth substrate.

According to an embodiment of the growth substrate, a cross-section area of the first regions in the semiconductor layer decreases starting from the main surface of the substrate. In particular, the cross-section area extends parallel to the main surface of the substrate. For example, the first regions comprise the shape of a, in particular stepped, truncated pyramid or a, in particular stepped, truncated cone. In a section perpendicular to the main surface of the substrate, a cross-section of the first regions comprises, for example, the shape of a trapezoid or a trapezoidal shape.

According to an embodiment of the growth substrate, the first regions and the second regions form a regular grid. For example, the regular grid is a hexagonal grid or a uniform rectangular grid. In particular, the first regions run along grid lines of the regular grid in top view. A top view is considered here and in the following to be, for example, a view of the growth substrate perpendicular to the main surface of the substrate. In particular, the first regions overlap the grid lines of the regular grid in top view.

According to an embodiment of the growth substrate, a dislocation density is greater in the first regions than in the second regions. In particular, this reduces internal stresses in the growth substrate. This leads, for example, to an improved lifetime and improved reliability of the growth substrate.

According to an embodiment of the growth substrate, the first regions do not comprise impurity atoms of the first type and/or the second type. Thus, a growth substrate is provided with a semiconductor layer comprising different material properties in different regions.

A radiation-emitting semiconductor chip is further specified. Preferably, the semiconductor chip comprises a growth substrate as described herein. Features and embodiments described in combination with the method for producing a growth substrate and the growth substrate also apply to the radiation-emitting semiconductor chip and vice versa.

According to an embodiment of the radiation-emitting semiconductor chip, the semiconductor chip comprises a substrate with a main surface, a semiconductor layer on the main surface of the substrate and an epitaxial semiconductor layer sequence. In particular, the substrate and the semiconductor layer form the growth substrate for the epitaxial semiconductor layer sequence. The epitaxial semiconductor layer comprises an active layer configured to generate electromagnetic radiation in the ultraviolet region of the electromagnetic spectrum. The semiconductor layer comprises a nitride compound semiconductor material and impurity atoms of a first type.

Due to the impurity atoms of the first type the thermal expansion coefficient of the semiconductor layer and thus also the thermal expansion coefficient of the growth substrate can be adapted to a thermal expansion coefficient of the epitaxial semiconductor layer sequence. This prevents, for example, the formation of cracks in the semiconductor layer sequence or reduces the curvature of the semiconductor layer sequence on the growth substrate.

The radiation-emitting semiconductor chip described herein comprises a reduced absorption of electromagnetic radiation due to the growth substrate with a low defect density. Therefore, a radiation-emitting semiconductor chip with an increased light extraction efficiency can be provided. For example, the reduced absorption is caused by passivation or removal of point defects, as is possible by the method for producing the growth substrate described herein.

According to an embodiment of the radiation-emitting semiconductor chip, the active layer comprises aluminum gallium nitride.

According to an embodiment of the radiation-emitting semiconductor chip, the semiconductor chip comprises a layer with n-doped aluminum gallium nitride. The layer serves in particular as a current distribution layer. The layer with n-doped aluminum gallium nitride can be grown as defect-free as possible on the semiconductor layer of the growth substrate described herein, for example, due to a possible influence on a lattice constant of the semiconductor layer by the impurity atoms of the first type and/or the impurity atoms of the second type. This in particular increases the efficiency of the radiation-emitting semiconductor chip as a current is distributed more evenly across the epitaxial semiconductor layer sequence.

According to an embodiment of the radiation-emitting semiconductor chip, the electromagnetic radiation generated by the active layer comprises a wavelength maximum in the region from 200 nanometers 315 nanometers, both inclusive. In other words, the active layer is configured to generate and emit electromagnetic radiation in the UVB and/or UVC region. The UVB region comprises in particular electromagnetic radiation with a wavelength from 280 nanometers to 315 nanometers, both inclusive. The UVC region comprises in particular electromagnetic radiation with a wavelength from 100 nanometers to 280 nanometers, both inclusive. For example, the active layer is configured to generate electromagnetic radiation with a wavelength maximum of at most 280 nanometers, in particular of at most 250 nanometers.

According to an embodiment of the radiation-emitting semiconductor chip, the semiconductor layer comprises aluminum nitride into which boron atoms are inserted as impurity atoms. In particular, the introduction of boron atoms increases the thermal conductivity of the semiconductor layer. In particular, this provides a semiconductor layer that enables effective cooling of the epitaxial semiconductor layer sequence.

Further advantageous embodiments, configurations, and developments of the method for producing a growth substrate, the growth substrate, and the radiation-emitting semiconductor chip are shown in the following exemplary embodiments shown in combination the figures.

### BRIEF SUMMARY OF THE FIGURES

FIGS. 1 to 3 show schematic sectional views of stages of a method for producing a growth substrate according to an exemplary embodiment.

FIG. 4 shows a schematic sectional view of a growth substrate according to an exemplary embodiment.

FIG. 5 shows a schematic sectional view of stages of a method for producing a growth substrate according to an exemplary embodiment.

FIGS. 6 and 7 show schematic sectional views of stages of a method for producing a growth substrate according to an exemplary embodiment.

FIGS. 8 and 9 show schematic exemplary embodiments of a mask on a semiconductor layer.

FIG. 10 shows a schematic sectional view of a growth substrate according to an exemplary embodiment.

FIG. 11 shows schematic sectional views of stages of a method for producing a growth substrate according to an exemplary embodiment.

FIG. 12 shows a schematic sectional view of a growth substrate according to an exemplary embodiment.

FIG. 13 shows a schematic sectional view of a radiation-emitting semiconductor chip according to an exemplary embodiment.

FIG. 14 shows full width at half maxima FWHM of various X-ray diffraction reflections measured on aluminum nitride as a function of a fluence during ion implantation of impurity atoms of a first type.

FIG. 15 shows SRIM simulations of defects in a semiconductor layer for ion implantation under different conditions.

FIG. 16 shows transmission spectra of a semiconductor layer.

### DETAILED DESCRIPTION

Elements that are identical, similar or have the same effect are marked with the same reference signs in the figures. The figures and the proportions of the elements shown in the figures should not be considered to be true to scale. Rather, individual elements, in particular layer thicknesses, may be shown in exaggerated size for better visualization and/or understanding.

In an exemplary embodiment of a method for producing a growth substrate 1, a substrate 2 is first provided, as shown in FIG. 1. The substrate 2 comprises a main surface 3. In the present case, the substrate 2 comprises or consists of sapphire.

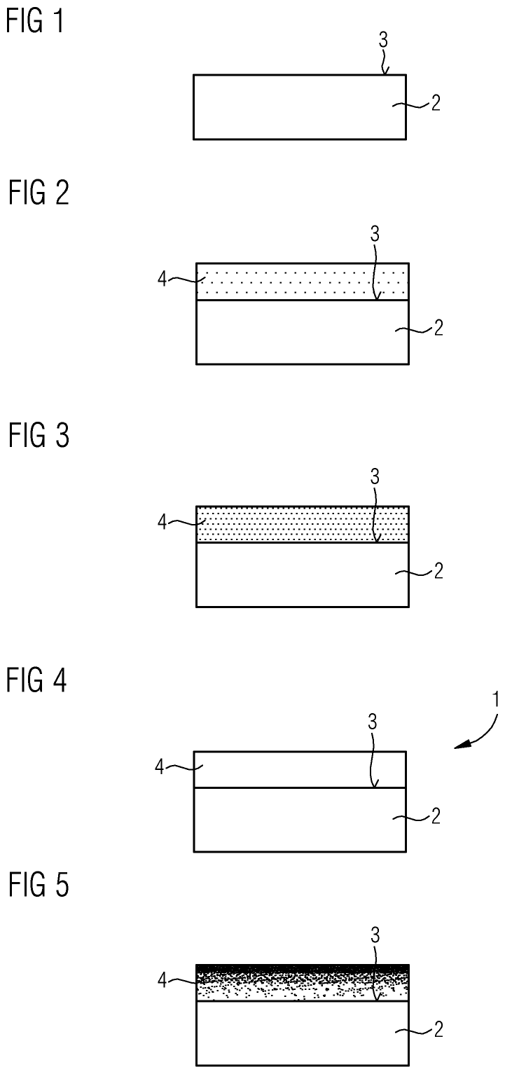

A semiconductor layer 4 is applied to the main surface 3 of the substrate 2, as shown in FIG. 2. The semiconductor layer 4 comprises a nitride compound semiconductor material. Presently, the semiconductor layer 4 comprises aluminum nitride. The semiconductor layer 4 is applied presently by sputtering or MOVPE. The semiconductor layer 4 applied in this way comprises a dislocation density of at least 1·10¹⁰ cm⁻².

Impurity atoms of a first type are inserted into the semiconductor layer 4 by ion implantation (FIG. 3). This increases the defect density in the semiconductor layer 4. In particular, the impurity atoms of the first type are inserted into the semiconductor layer 4 in a homogeneous distributed manner. During ion implantation, ions of the impurity atoms of the first type impinge on the semiconductor layer 4 with a fluence of approximately 5·10¹⁶ cm⁻². In particular, the impurity atoms of the first type are boron or gallium. The ion implantation occurs via a surface of the semiconductor layer 4 that is opposite the main surface 3 of the substrate 2. The ion implantation therefore does not occur through the substrate 2 into the semiconductor layer 4.

After inserting the impurity atoms of the first type, the semiconductor layer 4 is tempered. Tempering occurs for about one hour at approximately 1700° C. Due to the tempering the defect density, in particular the dislocation density, in the semiconductor layer 4 is reduced. After tempering, the semiconductor layer 4 comprises a dislocation density of at most 1·10⁹ cm⁻².

In the case where the impurity atoms of the first type are boron, the impurity atoms of the first type are incorporated into the semiconductor layer 4 during tempering so that aluminum boron nitride is formed in the semiconductor layer 4. If the impurity atoms of the first type are gallium, the impurity atoms of the first type are removed from the semiconductor layer 4 during tempering.

FIG. 4 shows a growth substrate 1 according to an exemplary embodiment, which can be produced, for example, with the method described in combination with FIGS. 1 to 3. The growth substrate comprises a substrate 2 with a main surface 3 and a semiconductor layer 4. The semiconductor layer 4 is arranged on the main surface 3 of the substrate 2. The semiconductor layer 4 comprises impurity atoms of a first type. The impurity atoms of the first type are presently boron and, in particular, are homogeneously distributed in the semiconductor layer 4. Thus, during the method of producing the growth substrate 1 according to the present exemplary embodiment, impurity atoms of the first type were introduced, which are incorporated into the semiconductor layer 4 by tempering. In addition to the impurity atoms of the first type, impurity atoms of a second type, such as silicon, magnesium, or oxygen, may also be present in the semiconductor layer 4.

In a method for producing a growth substrate 1 according to another exemplary embodiment, a substrate 2 having a main surface 3 is first provided and a semiconductor layer 4 is deposited on the main surface 3 of the substrate 2 as described in combination with FIGS. 1 and 2. However, in the present exemplary embodiment, the impurity atoms of the first type are inserted into the semiconductor layer 4 in a plurality of ion implantation steps. This results in particular in a gradient of the impurity atoms of the first type in the semiconductor layer 4, as shown in FIG. 5. This also creates a gradient of point defects in the semiconductor layer 4, which results in a graded stress in the semiconductor layer 4 starting from the main surface 3 of the substrate 2. For example, a concentration of the impurity atoms of the first type in the semiconductor layer 4 increases or decreases towards the main surface 3.

In order to generate the gradient in the semiconductor layer 4, the ion implantation steps differ in an acceleration energy of the ions of the impurity atoms. For example, the ions of the impurity atoms of the first type are accelerated in an ascending manner with the following acceleration energies: 10 keV, 20 keV, 30 keV, 40 keV. The total fluence of the ions is approximately 5·10¹⁶ cm⁻².

After the plurality of ion implantation steps, the semiconductor layer 4 is tempered at approximately 1700° C. for one hour. This provides a growth substrate 1 with a semiconductor layer 4 with a dislocation density of at most 5·10⁸ cm⁻². If impurity atoms of the first type are inserted into the semiconductor layer 4, which remain in the semiconductor layer 4 under the tempering conditions, the finished growth substrate 1 comprises a semiconductor layer 4 with a gradient of the impurity atoms of the first type.

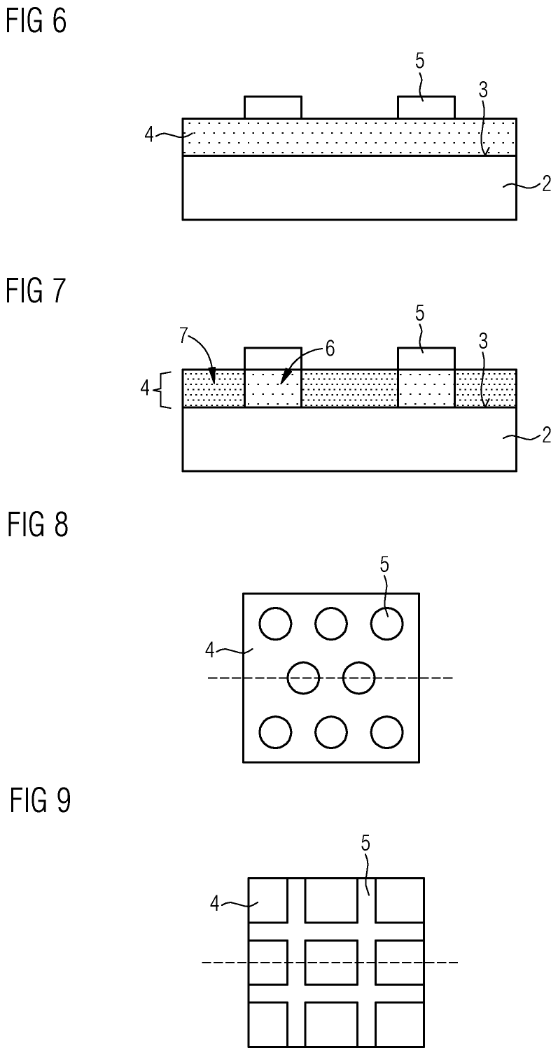

In combination with FIGS. 6 and 7, a further exemplary embodiment of a method for producing a growth substrate 1 is described. As already described together with FIGS. 1 and 2, a substrate 2 with a main surface 3 is provided and a semiconductor layer 4 is applied to the main surface 3 of the substrate 2. A mask 5 is then applied to the semiconductor layer 4, as shown in FIG. 6. The mask 5 only partially covers the semiconductor layer 4. The mask 5 comprises the shape of a regular grid. The mask 5 is formed, for example, from a photoresist and comprises a thickness such that the impurity atoms cannot penetrate the mask 5 during ion implantation. As an alternative to the photoresist, the mask 5 can also be formed of a metal such as Cr or Ti, silicon dioxide or silicon nitride. In particular, the mask 5 comprises a thickness of at most 5 micrometers.

After applying the mask 5, impurity atoms of a first type and/or impurity atoms of a second type are inserted into the semiconductor layer 4 by ion implantation. First regions 6 and second regions 7 are formed in the semiconductor layer 4, as shown in FIG. 7. No impurity atoms are inserted into the first regions 6, as they are covered by the mask 5. However, a surface of the second regions 7, which is opposite the main surface 3 of the substrate 2, is free of the mask 5, which is why impurity atoms of the first type and/or the second type are inserted into the second regions 7 by the ion implantation.

If the mask 5 is a mask 5 formed from a photoresist, the photoresist is removed before the semiconductor layer 4 is tempered. If the mask 5 comprises another material, it is in particular, alternatively possible, for the mask 5 to be removed after tempering. Tempering occurs at a temperature in a region of 1400° C. to 1800° C., both inclusive, for about one hour. After tempering and removal of the mask 5, the finished growth substrate 1 is obtained.

FIGS. 8 and 9 show exemplary embodiments of the mask 5 on the semiconductor layer 4. The semiconductor layer 4 and the mask 5 are shown in top view. In both figures, the mask 5 comprises a regular grid. The dashed lines specify the position of a cross-section in each case, so that the sectional view of FIGS. 6 and 7 is obtained.

In FIG. 8, the mask 5 is applied to the semiconductor layer 4 in such a way that the mask 5 covers intersections of a hexagonal grid. The mask 5 is applied to the semiconductor layer 4 in a circular or at least approximately circular shape.

In contrast, the mask 5, which is shown in FIG. 9, covers grid lines of a regular grid. In this case, the regular grid is a uniform rectangular grid.

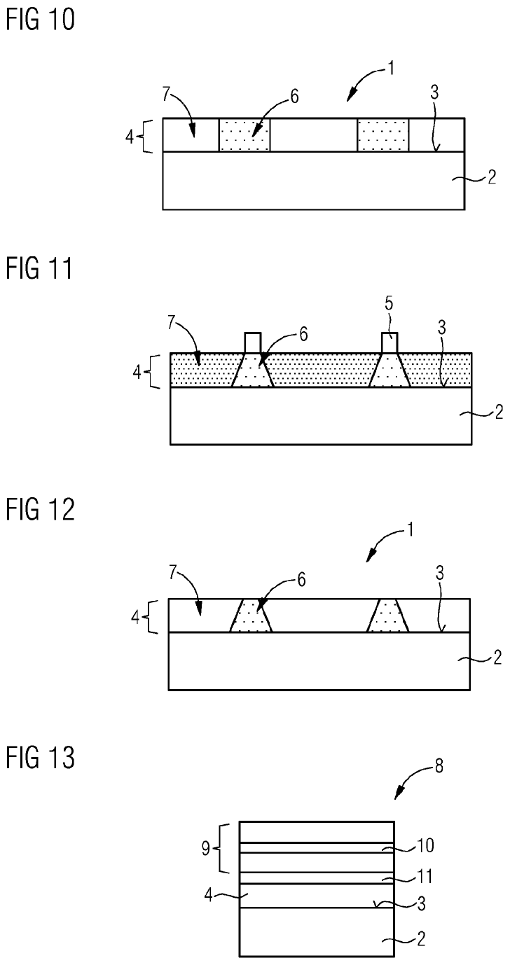

FIG. 10 shows an exemplary embodiment of a growth substrate 1 produced, for example, using the method for producing a growth substrate 1 described in combination with FIGS. 6 and 7. The growth substrate 1 comprises a substrate 2 with a main surface 3 to which a semiconductor layer 4 is applied, which comprises in particular aluminum nitride and into which impurity atoms of a first type are inserted. The semiconductor layer 4 comprises first regions 6 and second regions 7. The first regions 6 form a regular grid.

The first regions 6 and the second regions 7 differ in a defect density, in particular a dislocation density, and/or in a concentration of the impurity atoms of the first type. In particular, the first regions 6 comprise no impurity atoms of the first type. This can be explained by the fact that the first regions 6 were covered by a mask 5 during the method of producing the growth substrate 1. Alternatively or additionally, it is possible that the defect density, in particular the dislocation density, is greater in the first regions 6 than in the second regions 7.

In combination with FIG. 11, another exemplary embodiment of a method for producing a growth substrate 1 is described. First, as already described in combination with FIGS. 1 and 2, a substrate 2 having a main surface 3 is provided and a semiconductor layer 4 comprising a nitride compound semiconductor material is applied on the main surface 3. Then, analogous to FIGS. 6 and 7, a mask 5 is applied to the surface of the semiconductor layer 4 which is opposite to the main surface 3 and impurity atoms of a first type are inserted into the semiconductor layer 4 by ion implantation. In doing so, first regions 6 and second regions 7 are formed in the semiconductor layer 4. Due to the mask 5, no impurity atoms of the first type are inserted into the first regions 6.

After this first ion implantation step, part of the mask 5 is removed. A further ion implantation step is then carried out.

These two steps are repeated several times, with at least a part of the mask 5 being removed between two ion implantation steps. The individual ion implantation steps differ in particular by an acceleration energy of the ions of the impurity atoms of the first type. The acceleration energy is reduced with an increasing number of ion implantation steps. As a result, the impurity atoms of the first type penetrate less and less deeply into the semiconductor layer 4. In this way, first regions 6 are formed, which become smaller in a direction leading away from the main surface 3 of the substrate 2 when viewed in a cross-section. In the case where the mask is applied in a circular or near-circular shape to intersections of grid lines of a regular grid, the first regions 6 may comprise a frustoconical extension as shown in FIG. 8.

After performing the plurality of ion implantation steps, the mask 5 is removed from the semiconductor layer 4 and the semiconductor layer 4 is tempered at about 1700° C. for about one hour.

FIG. 12 shows an exemplary embodiment of a growth substrate 1, which can be produced in particular by the method for producing a growth substrate 1 described in combination with FIG. 11. The growth substrate 1 comprises a substrate 2 comprising sapphire. A semiconductor layer 4 is applied to a main surface 3 of the substrate 2. The semiconductor layer 4 comprises a nitride compound semiconductor material, in particular aluminum nitride, and impurity atoms of a first type. The impurity atoms of the first type are boron, for example. It is also possible that the semiconductor layer 4 comprises impurity atoms of a second type.

The semiconductor layer 4 comprises first regions 6 and second regions 7. The first regions 6 are free of impurity atoms of the first type and form a regular grid. Viewed in cross-section, the first regions 6 decrease in size starting from the main surface 3 of the substrate 2 towards a surface of the semiconductor layer 4 which is opposite the main surface 3 of the substrate 2.

An exemplary embodiment of a radiation-emitting semiconductor chip 8 is shown in FIG. 13. The radiation-emitting semiconductor chip 8 comprises a growth substrate 1 and an epitaxial semiconductor layer sequence 9. Presently, the growth substrate 1 comprises a substrate 2 comprising, for example, sapphire, and a semiconductor layer 4 comprising a nitride compound semiconductor material, such as aluminum nitride, and impurity atoms of a first type, such as boron. The semiconductor layer 4 is arranged on a main surface 3 of the substrate 2.

The epitaxial semiconductor layer sequence 9 is arranged on the semiconductor layer 4. The semiconductor layer 4 is thus located between the substrate 2 and the epitaxial semiconductor layer sequence 9. The epitaxial semiconductor layer sequence 9 comprises an active layer 10. The active layer 10 comprises aluminum gallium nitride and is configured to generate electromagnetic radiation in the ultraviolet region of the electromagnetic spectrum. For example, a wavelength maximum of the electromagnetic radiation generated is between 200 nanometers and 315 nanometers, both inclusive.

It is possible that, as shown in FIG. 13, an n-doped aluminum gallium nitride layer 11 is arranged between the epitaxial semiconductor layer sequence 9 and the semiconductor layer 4 for current distribution.

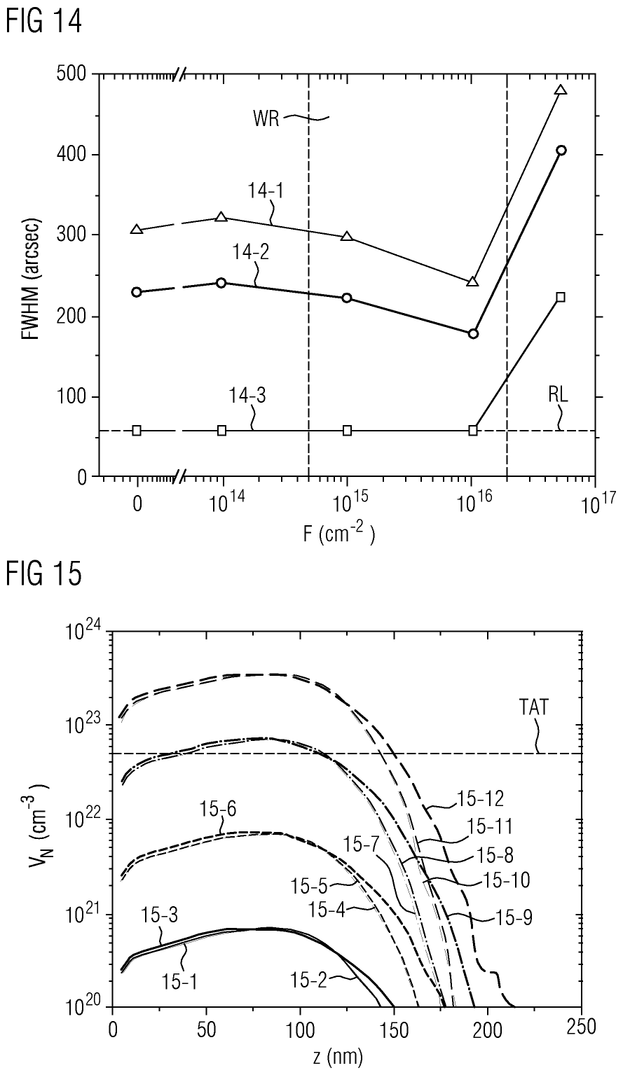

FIG. 14 shows a dependency of a full width at half maximum (FWHM) of X-ray diffraction reflections of a semiconductor layer 4 with aluminum nitride on a fluence (F) during an ion implantation of impurity atoms of a first type. The aluminum nitride was grown with MOVPE and tempered after ion implantation. The impurity atoms of the first type are boron. Ion implantation occurred with an acceleration energy of the boron ions of 40 keV. The full width at half maximum of the X-ray diffraction reflections of aluminum nitride are specified in arcsec and the fluence in cm⁻². The dashed line RL shows the resolution limit during the X-ray diffraction experiment.

Curve 14-1 shows the full width at half maximum of the (202̅1) reflection of aluminum nitride as a function of fluence during ion implantation. Curve 14-2 shows the full width at half maximum of the (101̅2) reflection of aluminum nitride as a function of fluence during ion implantation. Curve 14-3 shows the full width at half maximum of the (0002) reflection of aluminum nitride as a function of the fluence during ion implantation. The first measurement point shows the full width at half maximum of the reflections of aluminum nitride, which comprises no boron atoms.

The full width at half maximum of the X-ray diffraction reflections can be used as a measure of crystallinity and therefore as a measure of the quality of a material. Generally, the crystal quality increases with decreasing full width at half maximum. In particular, a low full width at half maximum of the reflections also indicates a low defect density.

From the shape of the curves 14-1, 14-2, and 14-3, it can be in particular concluded that the region WR is a suitable working region for the fluence during the ion implantation of boron. The full width at half maximum of the reflections increases sharply at a fluence of over 1·10¹⁶ cm⁻². The semiconductor layer thus comprises a high defect density at high fluences.

FIG. 15 shows SRIM simulations of defects in a semiconductor layer 4 for ion implantations under different conditions. SRIM, short for “Stopping and Range of Ions in Matter”, is a software with which, among other things, a theoretical amorphization threshold of semiconductor materials can be calculated.

In FIG. 15 a concentration of nitrogen vacancies Vₙ in cm⁻³ is shown against a depth z in nanometers in a semiconductor layer with aluminum nitride. The dashed line TAT is the theoretical amorphization threshold (TAT) of aluminum nitride. The parameters for the SRIM simulation of the ion implantation of the different curves are summarized in the following table.

TABLE 1
Parameters for the SRIM simulation of ion
implantation for the curves in FIG. 15.

| | impurity | acceleration | fluence |
|---|---|---|---|
| curve | atom | energy in keV | in cm⁻² |
| 15-1 | B | 40 | 1 · 10¹⁴ |
| 15-2 | C | 47.5 | 8.1 · 10¹³ |
| 15-3 | Ne | 70 | 4.1 · 10¹³ |
| 15-4 | B | 40 | 1 · 10¹⁵ |
| 15-5 | C | 47.5 | 8.1 · 10¹⁴ |
| 15-6 | Ne | 70 | 4.1 · 10¹⁴ |
| 15-7 | B | 40 | 1 · 10¹⁶ |
| 15-8 | C | 47.5 | 8.1 · 10¹⁵ |
| 15-9 | Ne | 70 | 4.1 · 10¹⁵ |
| 15-10 | B | 40 | 5 · 10¹⁶ |
| 15-11 | C | 47.5 | 4.05 · 10¹⁶ |
| 15-12 | Ne | 70 | 2.05 · 10¹⁶ |

The curves show that with boron as the impurity atom of the first type, the theoretical amorphization threshold of aluminum nitride can be exceeded at fluences greater than or equal to 1·10¹⁶ cm⁻². With carbon as the impurity atom of the first type, on the other hand, the theoretical amorphization threshold of aluminum nitride can already be exceeded at a fluence of greater than or equal to 8.1·10¹⁵ cm⁻² and with neon as the impurity atom of the first type already at a fluence of greater than or equal to 4.1·10¹⁵ cm⁻².

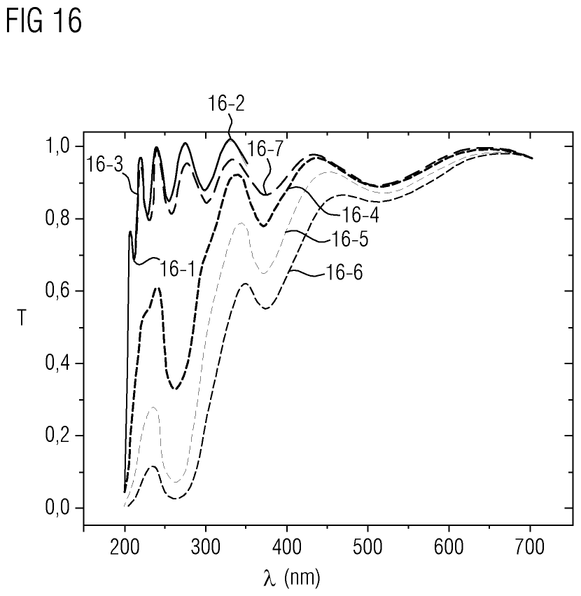

FIG. 16 shows transmission spectra 16-1 to 16-7 of a respective semiconductor layer 4 in a region from 150 nanometers to 750 nanometers, both inclusive. The semiconductor layers 4 comprising the transmission spectra 16-1 to 16-6 have impurity atoms of a first type, while the semiconductor layer with the transmission spectrum 16-7 is free of impurity atoms. Presently, the semiconductor layers 4 comprise aluminum nitride. The impurity atoms of the first type are boron.

Table 2 summarizes the most important parameters during producing the semiconductor layers 4 comprising the transmission spectra 16-1 to 16-7.

TABLE 2
Parameters during producing the semiconductor layers
4 comprising the transmission spectra 16-1 to 16-7.

| transmission | fluence | |
|---|---|---|
| spectrum | in cm⁻² | tempering |
| 16-1 | 1 · 10¹⁶ | Yes |
| 16-2 | 1 · 10¹⁵ | Yes |
| 16-3 | 1 · 10¹⁴ | Yes |
| 16-4 | 1 · 10¹⁶ | No |
| 16-5 | 1 · 10¹⁵ | No |
| 16-6 | 1 · 10¹⁴ | No |
| 16-7 | — | No |

A high transmission is associated in particular with a low defect density of the semiconductor layer 4. FIG. 16 clearly shows this effect. The non-tempered semiconductor layers 4 of the transmission spectra 16-4 to 16-7 show a lower transmission for electromagnetic radiation in the ultraviolet wavelength range of the electromagnetic spectrum. Compared to the non-tempered semiconductor layer 4 without impurity atoms of the first type, the tempered semiconductor layers 4 with impurity atoms of the first type comprise a better transmission for electromagnetic radiation in the ultraviolet wavelength range.

The features and exemplary embodiments described in combination with the figures may be combined with each other in accordance with further exemplary embodiments, even if not all combinations are explicitly described. Furthermore, the exemplary embodiments described in combination with the figures may alternatively or additionally comprise further features as described in the general part.

This patent application claims the priority of the German patent application 102022108234.2, the disclosure content of which is hereby incorporated by reference.

The invention is not limited to the exemplary embodiments by the description thereof. Rather, the invention includes any new feature as well as any combination of features, which includes in particular any combination of features in the patent claims, even if this feature or combination itself is not explicitly specified in the patent claims or exemplary embodiments.

### LIST OF REFERENCE SIGNS

1 growth substrate
2 substrate
3 main surface
4 semiconductor layer
5 mask
6 first regions
7 second regions
8 radiation-emitting semiconductor chip
9 epitaxial semiconductor layer sequence
10 active layer
11 layer with n-doped aluminum gallium nitride
RL resolution limit
WR working region
TAT theoretical amorphization threshold

1. A method for producing a growth substrate comprising:
providing a substrate with a main surface,
applying a semiconductor layer comprising a nitride compound semiconductor material to the main surface of the substrate,
inserting of impurity atoms of a first type into the semiconductor layer by ion implantation,
tempering of the semiconductor layer after inserting the impurity atoms of the first type, wherein
the impurity atoms of the first type are removed from the semiconductor layer by the tempering.

2. The method for producing a growth substrate according to claim 1, wherein
impurity atoms of a second type are inserted into the semiconductor layer by ion implantation, and
the impurity atoms of the second type are different from the impurity atoms of the first type.

3. The method for producing a growth substrate according to claim 1, wherein
the impurity atoms of the first type and/or the impurity atoms of the second type are selected from the group formed from the following elements: Be, Mg, B, Al, Ga, In, C, Si, Ge, N, P, As, O, He, Ne, Ar.

4. The method for producing a growth substrate according to claim 1, wherein
the semiconductor layer comprises aluminum nitride and the impurity atoms of the first type are boron.

5. The method for producing a growth substrate according to claim 1, wherein
tempering is carried out at a temperature from 1400° C. to 1800° C., both inclusive.

6. The method for producing a growth substrate according to claim 1, wherein
during the ion implantation, ions of the impurity atoms of the first type and/or ions of the impurity atoms of the second type impinge on the semiconductor layer with a fluence between 5·10¹⁴ cm⁻² and 5·10¹⁶ cm⁻², both inclusive.

7. The method for producing a growth substrate according to claim 1, wherein
during the ion implantation, the ions of the impurity atoms of the first type and/or the ions of the impurity atoms of the second type are accelerated with an acceleration energy of between 10 keV and 1000 keV, both inclusive.

8. The method for producing a growth substrate according to claim 1, wherein
the semiconductor layer comprises a dislocation density of at most 1·10⁹ cm⁻² after tempering.

9. The method for producing a growth substrate according to claim 1, wherein
a plurality of ion implantation steps is performed during inserting the impurity atoms of the first type and/or the impurity atoms of the second type, and
the impurity atoms and/or the acceleration energies of the ions differ between different ion implantation steps.

10. The method for producing a growth substrate according to claim 1, wherein
a mask is applied in places to the semiconductor layer before inserting the impurity atoms of the first type and/or the impurity atoms of the second type.

11. The method for producing a growth substrate according to claim 10, wherein
a plurality of ion implantation steps is performed, and
at least a part of the mask is removed between two ion implantation steps.

12. A growth substrate comprising:
a substrate with a main surface, and
a semiconductor layer comprising a nitride compound semiconductor material on the main surface of the substrate, wherein
the semiconductor layer comprises impurity atoms of a first type, and
the semiconductor layer comprises first regions and second regions, and
a cross-section area of the first regions decreases starting from the main surface of the substrate.

13. The growth substrate according to claim 12, in which the semiconductor layer comprises, starting from the main surface of the substrate, a gradient of impurity atoms of the first type and/or a gradient of impurity atoms of a second type.

14. (canceled)

15. The growth substrate according to claim 12, in which
the semiconductor layer comprises first regions and second regions, wherein
the first regions form a regular grid, and
a dislocation density in the first regions is greater than in the second regions.

16. The growth substrate according to claim 12, in which
the semiconductor layer comprises first regions and second regions, wherein
the first regions form a regular grid, and
the first regions comprise no impurity atoms of the first type and/or no impurity atoms of the second type.

17. A radiation-emitting semiconductor chip comprising:
a substrate with a main surface,
a semiconductor layer on the main surface of the substrate, and
an epitaxial semiconductor layer sequence on the semiconductor layer, wherein
the epitaxial semiconductor layer sequence comprises an active layer configured to generate electromagnetic radiation in the ultraviolet region of the electromagnetic spectrum,
the semiconductor layer comprises a nitride compound semiconductor material,
the semiconductor layer comprises impurity atoms of a first type, and
the semiconductor layer comprises first regions and second regions, and
a cross-section area of the first regions decreases starting from the main surface of the substrate.

18. The radiation-emitting semiconductor chip according to claim 17, in which
the active layer comprises aluminum gallium nitride.

19. The radiation-emitting semiconductor chip according to claim 17, in which
the electromagnetic radiation comprises a wavelength maximum in the region from 200 nanometers to 315 nanometers, both inclusive.

20. The radiation-emitting semiconductor chip according to claim 17, in which
the semiconductor layer comprises aluminum nitride into which boron atoms are inserted as impurity atoms of the first type.
